(19) United States
(12) Patent Application Publication
(10) Pub. No.: US 2023/0076282 A1
(43) Pub. Date: Mar. 9, 2023

(54) DISPLAY PANEL AND DISPLAY APPARATUS

(71) Applicant: WUHAN TIANMA MICROELECTRONICS CO., LTD., Wuhan (CN)

(72) Inventors: Yu CAI, Wuhan (CN); Jiaxian LIU, Shanghai (CN)

(73) Assignee: WUHAN TIANMA MICROELECTRONICS CO., LTD., Wuhan (CN)

(21) Appl. No.: 18/049,025

(22) Filed: Oct. 24, 2022

(30) Foreign Application Priority Data
Aug. 18, 2022 (CN) 202210990824.2

(51) Int. Cl. H01L 51/52; H01L 27/32

(52) U.S. Cl. CPC H01L 51/5275; H01L 27/322; H01L 51/5284

(57) ABSTRACT

A display panel and a display apparatus are provided. The display panel includes a substrate, a light-emitting element layer located on a side of the substrate and including light-emitting elements, and a light extraction layer located on a side of the light-emitting element layer away from the substrate. The light extraction layer includes a first refractive index unit and a second refractive index unit that have different refractive indices. In a direction perpendicular to a plane of the substrate, one first refractive index unit overlaps one light-emitting element. The first refractive index unit includes a central portion and a functional portion surrounding the central portion, and a thickness of the functional portion changes gradually in a direction from the central portion to the functional portion. The second refractive index unit is located on a side of the first refractive index unit away from the substrate, and covers the functional portion.

### CROSS-REFERENCE TO RELATED APPLICATION

The present disclosure claims priority to Chinese Patent Application No. 202210990824.2, filed on Aug. 18, 2022, the content of which is incorporated herein by reference in its entirety.

### TECHNICAL FIELD

The present disclosure relates to the field of display technologies, and in particular, to a display panel and a display apparatus.

### BACKGROUND

The organic light-emitting diode (OLED) has a self-luminous property, and does not require additional light sources, which is beneficial to thinning of an overall display apparatus, thereby realizing the production of flexible display screens. The OLED display panels further have the advantages of high brightness, low power consumption, fast response, high definition, good flexibility, and high light extraction efficiency, which can meet the new requirements for consumers of display technology. However, part of large-angle light emitted by the light-emitting element in the organic light-emitting display technology in the related art is restricted inside the display panel, and cannot be emitted from the display panel to contribute to light emission of pixels, which affects the overall light-extraction efficiency of the light-emitting element.

### SUMMARY

A first aspect of the present disclosure provides a display panel. The display panel includes a substrate, a light-emitting element layer located on a side of the substrate and including light-emitting elements, and a light extraction layer located on a side of the light-emitting element layer away from the substrate. The light extraction layer includes at least one first refractive index unit and a second refractive index unit, and a refractive index of each of the at least one first refractive index unit is different from a refractive index of the second refractive index unit. In a direction perpendicular to a plane of the substrate, one of the at least one first refractive index unit overlaps one of the light-emitting elements. Each of the at least one first refractive index unit includes a central portion and a functional portion surrounding the central portion. The functional portion has a thickness changing gradually in a direction from the central portion to the functional portion. The second refractive index unit is located on a side of the at least one first refractive index unit away from the substrate and covers at least the functional portion.

A second aspect of the present disclosure provides a display apparatus. The display apparatus includes a display panel. The display panel includes a substrate, a light-emitting element layer located on a side of the substrate and including light-emitting elements, and a light extraction layer located on a side of the light-emitting element layer away from the substrate. The light extraction layer includes at least one first refractive index unit and a second refractive index unit, and a refractive index of each of the at least one first refractive index unit is different from a refractive index of the second refractive index unit. In a direction perpendicular to a plane of the substrate, one of the at least one first refractive index unit overlaps one of the light-emitting elements. Each of the at least one first refractive index unit includes a central portion and a functional portion surrounding the central portion. The functional portion has a thickness changing gradually in a direction from the central portion to the functional portion. The second refractive index unit is located on a side of the at least one first refractive index unit away from the substrate and covers at least the functional portion.

### BRIEF DESCRIPTION OF DRAWINGS

In order to more clearly illustrate technical solutions of embodiments of the present disclosure, the accompanying drawings used in the embodiments are briefly described below. The drawings described below are merely a part of the embodiments of the present disclosure.

Based on these drawings, those skilled in the art can obtain other drawings.

FIG. 1 is a partial schematic diagram of a display panel according to some embodiments of the present disclosure;

FIG. 2 is a cross-sectional view along line AA′ shown in FIG. 1 according to some embodiments of the present disclosure;

FIG. 3 is another schematic diagram of a display panel according to some embodiments of the present disclosure;

FIG. 4 is another schematic diagram of a display panel according to some embodiments of the present disclosure;

FIG. 5 is another schematic diagram of a display panel according to some embodiments of the present disclosure;

FIG. 6 is another schematic diagram of a display panel according to some embodiments of the present disclosure;

FIG. 7 is another schematic diagram of a display panel according to some embodiments of the present disclosure;

FIG. 8 is another schematic diagram of a display panel according to some embodiments of the present disclosure;

FIG. 9 is another schematic diagram of a display panel according to some embodiments of the present disclosure;

FIG. 10 is another schematic diagram of a display panel according to some embodiments of the present disclosure;

FIG. 11 is a cross-sectional view along line BB′ in FIG. 10 according to some embodiments of the present disclosure;

FIG. 12 is another schematic diagram of a display panel according to some embodiments of the present disclosure;

FIG. 13 is another schematic diagram of a display panel according to some embodiments of the present disclosure;

FIG. 14 is another partial schematic diagram of a display panel according to some embodiments of the present disclosure;

FIG. 15 is another partial schematic diagram of a display panel according to some embodiments of the present disclosure;

FIG. 16 is another cross-sectional view along line BB′ in FIG. 10 according to some embodiments of the present disclosure;

FIG. 17 is another partial schematic diagram of a display panel according to some embodiments of the present disclosure;

FIG. 18 is another cross-sectional view along line BB′ in FIG. 10 according to some embodiments of the present disclosure;

FIG. 19 is another schematic diagram of a display panel according to some embodiments of the present disclosure; and

FIG. 20 is another schematic diagram of a display apparatus according to some embodiments of the present disclosure.

### DESCRIPTION OF EMBODIMENTS

In order to more clearly illustrate objectives, technical solutions, and advantages of the embodiments of the present disclosure, the technical solutions in the embodiments of the present disclosure are described in detail with reference to the accompanying drawings. The described embodiments are merely some of the embodiments of the present disclosure rather than all of the embodiments. All other embodiments obtained by those skilled in the art based on the embodiments of the present disclosure shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiments of the present disclosure and the attached claims are also intended to include plural forms thereof, unless noted otherwise.

In order to solve the problems in the related art, some embodiments of the present disclosure provide a display panel. A light extraction layer is provided on a light-emitting side of the light-emitting element in the display panel, and a functional interface formed between refractive index units with different refractive indices in the light extraction layer is used to deflect light with a large angle, so that an angle between the light after the deflection and the front viewing direction of the display panel is reduced, improving the probability of the light to emit from the display panel, and improving the light extraction efficiency of the light-emitting elements.

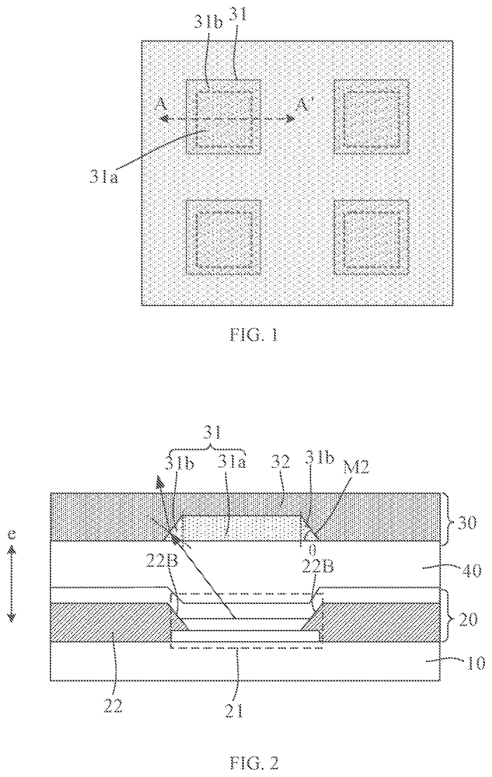

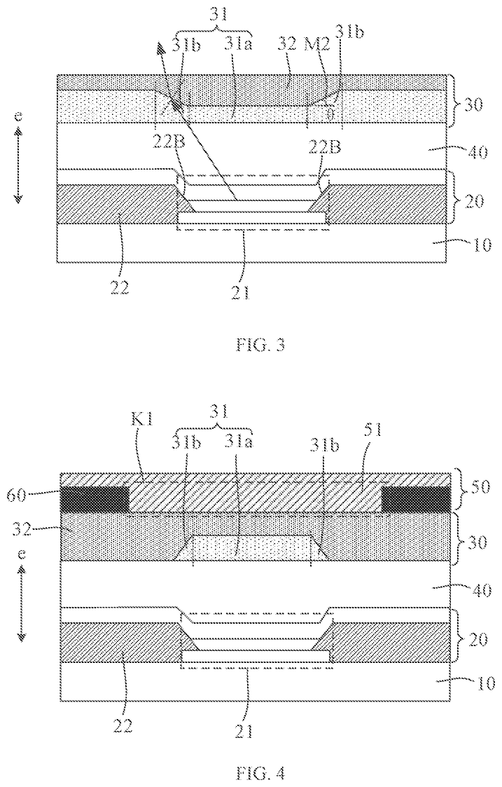

FIG. 1 is a partial schematic diagram of a display panel according to some embodiments of the present disclosure, FIG. 2 is a cross-sectional view along line AA′ shown in FIG. 1 according to some embodiments of the present disclosure, and FIG. 3 is another schematic diagram of a display panel according to some embodiments of the present disclosure.

FIG. 1 and FIG. 2 are referred to for understanding of the structure of the display panel provided by the embodiments of the present disclosure. Only the first refractive index unit 31 in a light extraction layer 30 is illustrated in FIG. 1. The first refractive index unit 31 is a graphical structure in the top view of FIG. 1. A shape of the first refractive index unit 31 is schematically represented, which is not intended to limit the present disclosure. Specifically, the shape of the first refractive index unit 31 can be designed according to the shape of the light-emitting element in the display panel.

As shown in FIG. 2, the display panel includes a substrate 10, a light-emitting element layer 20, and a light extraction layer 30. The light-emitting element layer 20 is located on a side of the substrate 10. The light-emitting element layer 20 includes multiple light-emitting elements 21 and a pixel definition layer 22. The pixel definition layer 22 is configured to separate adjacent light-emitting elements 21 from each other. The light-emitting element 21 is an organic light-emitting diode or an inorganic light-emitting diode. The light-emitting element 21 in FIG. 2 is merely a simplified illustration. In some embodiments, the light-emitting element 21 includes a first electrode, a light-emitting layer, and a second electrode that are stacked. The display panel further includes a pixel circuit located between the substrate 10 and the light-emitting element layer 20. The pixel circuit is coupled with the light-emitting element 21. The pixel circuit is configured to drive the light-emitting element 21 to emit light. An encapsulation layer 40 is further provided on a side of the light-emitting element layer 20 away from the substrate 10. The encapsulation layer 40 is configured to encapsulate the light-emitting element 21 to isolate water and oxygen so as to ensure the service life of the light-emitting element 21. In some embodiments, the encapsulation layer 40 is a rigid encapsulation, and the encapsulation layer 40 includes an encapsulation glass. In other embodiments, the encapsulation layer 40 is a flexible encapsulation, and the encapsulation layer 40 includes at least one inorganic encapsulation layer and at least one organic encapsulation layer.

The light extraction layer 30 is located on a side of the light-emitting element layer 20 away from the substrate 10. The light extraction layer 30 includes a first refractive index unit 31 and a second refractive index unit 32 that have different refractive indices.

In a direction e that is perpendicular to the plane of the substrate 10, the first refractive index unit 31 overlaps the light-emitting element 21. The first refractive index unit 31 includes a central portion 31a and a functional portion 31b. It can be seen from FIG. 1 that the functional portion 31b surrounds the central portion 31a.

The second refractive index unit 32 is located on a side of the first refractive index unit 31 away from the substrate 10. The second refractive index unit 32 covers at least the functional portion 31b. A thickness of the functional portion 31b gradually changes in a direction from the center portion 31a to the functional portion 31b. As shown in FIG. 2, the thickness of the functional portion 31b gradually decreases in the direction from the central portion 31a to the functional portion 31b. In other words, in a direction that is parallel to the plane of the substrate 10 and that is the direction from the center of the light-emitting element 21 to the edge of the light-emitting element 21, the thickness of the functional portion 31b gradually decreases. In other embodiments, as shown in FIG. 3, the thickness of the functional portion 31b gradually increases in the direction from the central portion 31a to the functional portion 31b. In the embodiments of FIG. 3, the surrounding arrangement between the functional portion 31b and the central portion 31a can be understood with reference to FIG. 1.

In some embodiments of FIG. 2, the thickness of the functional portion 31b gradually decreases in the direction from the central portion 31a to the functional portion 31b, and a refractive index of the first refractive index unit 31 is greater than a refractive index of the second refractive index unit 32. A part of the large-angle light emitted by the light-emitting element 21 will first enter the functional portion 31b, and then enter the second refractive index unit 32 through the functional portion 31b, and then the light will be refracted on an interface where the functional portion 31b is in contact with the second refractive index unit 32. The large-angle light refers to light emitted by the light-emitting element 21 with a large angle from the front viewing direction of the display panel. The front viewing direction of the user when using the display panel is a direction perpendicular to the display panel. It can be understood that the front viewing direction is parallel to a direction e perpendicular to the plane of the substrate 10. When the light emitted by the light-emitting element 21 propagates along the direction e perpendicular to the plane of the substrate 10, the angle between the light and the front viewing direction is zero. According to the refraction law of light, when light enters a medium from an optically denser medium, the incident angle of the light is smaller than the refraction angle. In the embodiments of FIG. 2, the large-angle light enters the second refractive index unit 32 through the functional portion 31b and then is refracted, and the propagation direction of the light is deflected toward the front viewing direction of the display panel, so that the angle between the light and the front viewing direction becomes smaller, thereby increasing the probability of light emitted from the display panel, and increasing the light extraction efficiency of the light-emitting element 21.

In some embodiments of FIG. 3, the thickness of the functional portion 31b increases gradually in a direction from the central portion 31a to the functional portion 31b, and a refractive index of the first refractive index unit 31 is smaller than a refractive index of the second refractive index unit 32. When part of the large-angle light emitted by the light-emitting element 21 enters the second refractive index unit 32 through the functional portion 31b, the light will be refracted on the interface where the functional portion 31b is in contact with the second refractive index unit 32. At this time, the light enters the light beam medium from the optically denser medium, and the incident angle of the light is smaller than the refraction angle. As shown in the embodiments of FIG. 3, the large-angle light enters the second refractive index unit 32 through the functional portion 31b and then is refracted, and the propagation direction of the light is deflected toward the front viewing direction of the display panel, so that the angle between the light and the front viewing direction becomes smaller, thereby increasing the probability of light emitted from the display panel, and increasing the light extraction efficiency of the light-emitting element 21.

In the display panel provided by the embodiments of the present disclosure, the light extraction layer 30 is provided on the side of the light-emitting element 21 away from the substrate 10. The first refractive index unit 31 in the light extraction layer 30 overlaps the light-emitting element 21. The first refractive index unit 31 includes a central portion 31a and a functional portion 31b. A thickness of the functional portion 31b gradually changes in a direction from the central portion 31a to the functional portion 31b. The second refractive index unit 32 covers the functional portion 31b. The relationship between the refractive index of the first refractive index unit 31 and the refractive index of the second refractive index unit 32 cooperates with the thickness variation of the functional portion 31b, so that the interface where the functional portion 31b is in contact with the second refractive index unit 32 forms a functional interface. When part of the large-angle light emitted by the light-emitting element 21 enters the second refractive index unit 32 through the functional portion 31b, it will be refracted on the interface between the second refractive index unit 32 and the functional portion 31b, and the refracted light will be deflected toward the front viewing direction of the display panel, so that the angle between the light and the front viewing direction becomes smaller, thereby increasing the probability of light emitted from the display panel, and increasing the light extraction efficiency of the light-emitting element 21.

In some embodiments of the present disclosure, the relationship between the refractive index of the first refractive index unit 31 and the refractive index of the second refractive index unit 32 cooperates with the thickness change of the functional portion 31b, so that the interface where the functional portion 31b is in contact with the second refractive index unit 32 forms a functional interface. For example, in some examples, the refractive index of the first refractive index unit 31 is greater than the refractive index of the second refractive index unit 32, and the thickness of the functional portion 31b gradually decreases in the direction from the central portion 31a to the functional portion 31b.

FIG. 4 is a schematic diagram of a display panel according to some embodiments of the present disclosure. In some embodiments, as shown in FIG. 4, the display panel includes a color filter layer 50. The color filter layer 50 includes a color filter unit 51 located on the side of the light extraction layer 30 away from the light-emitting element layer 20. The refractive index of the first refractive index unit 31 is greater than the refractive index of the second refractive index unit 32. The display panel further includes a black matrix 60. The black matrix 60 has a first opening K1. In the direction e perpendicular to the plane of the substrate 10, the first opening K1 overlaps the light-emitting element 21, and the black matrix 60 overlaps the pixel definition layer 22. The position of the black matrix 60 in FIG. 4 is only shown schematically. In some embodiments of the present disclosure, the color filter units 51 include at least a red color filter unit, a green color filter unit, and a blue color filter unit. The color filter unit 51 has a light filtering function, which can transmit light of a specific color and can filter light of other colors other than the specific color. For example, the red color filter unit can transmit red light. In the disclosure, the red light in the ambient light can penetrate the red color filter unit, and the red light cannot be emitted by the adjacent color filter units of other colors after being reflected by the structure below the red color filter unit, so that the reflected light is limited within the panel without being emitted out, thereby reducing the reflectivity of the display panel to ambient light. The color filter layer 50 in the embodiments of the present disclosure is equivalent to an anti-reflection layer, so that it has the function of reducing the reflection of the display panel to ambient light, thereby improving the display effect of the display panel.

In the embodiments of FIG. 4, the refractive index of the color filter unit 51 is smaller than the refractive index of the first refractive index unit 31. That is, the refractive index of the color filter unit 51 is smaller than the refractive index of the high-refractive material in the light extraction layer 30. In the display panel including the color filter layer 50 and the light extraction layer 30, the light extraction layer 30 can be used to increase the light extraction efficiency of the light-emitting element 21, and the color filter layer 50 can be used to reduce the reflectivity of the display panel to ambient light. If the color filter unit 51 is located on the side of the light extraction layer 30 away from the substrate 10, in a module structure in which the light extraction layer 30 and the color filter layer 50 are stacked, the layer with a smaller refractive index is located at the outmost side of the module structure, and a difference between the refractive index of the module structure and the refractive index of the layer (such as optical adhesive or protective cover) above the module structure can be reduced, thereby reducing the surface reflectivity of the outer surface of the module structure, thereby reducing the reflectivity of the display panel to ambient light, and improving the display effect.

In some embodiments of the present disclosure, the first refractive index unit 31 is a patterned structure, the first refractive index unit 31 overlaps the light-emitting element 21, and is covered by the second refractive index unit 32 From the overall view of the display panel, in some embodiments, the second refractive index unit 32 is a continuous whole layer, and the second refractive index unit 32 covers multiple first refractive index units 31, so that the second refractive index units 32 can provide a relatively flat substrate for manufacturing the layer over the light extraction layer 30. In other embodiments, the second refractive index unit 32 is a patterned structure, and the second refractive index unit 32 at least cover the functional portion 31b in the first refractive index unit 31.

In some embodiments of the present disclosure, as shown in FIG. 2 or FIG. 3, the pixel definition layer 22 has a second opening, and the light-emitting element 21 is located in the second opening. The second opening is not marked in the drawings, but a side wall 22B of the second opening is marked. In the direction e perpendicular to the plane of the substrate 10, at least a part of the functional portion 31b overlaps the side wall 22B. Such configuration can ensure that the large-angle light emitted by the light-emitting element 21 can irradiate on the interface where the functional portion 31b is in contact with the second refractive index unit 32, so as to utilize the interface where the functional portion 31b and the second refractive index unit 32 are in contact with each other to refract the large-angle light, so that the refracted light is deflected toward the front viewing direction of the display panel, thereby increasing the light extraction efficiency of the light-emitting element 21.

FIG. 5 is a schematic diagram of a display panel according to some embodiments of the present disclosure. In some embodiments, as shown in FIG. 5, the display panel includes a color filter unit 51, and the second refractive index unit 32 is reused as a color filter unit 51. The refractive index of the first refractive index unit 31 is greater than the refractive index of the second refractive index unit 32. In other words, the color filter unit 51 is reused as a low refractive index layer in the light extraction layer 30. In some embodiments, the second refractive index unit 32 has a function of increasing the light extraction efficiency of the light-emitting element 21 by cooperating with the first refractive index unit 31, and the second refractive index unit 32 has a characteristic of filtering, which can be used to reduce reflection of the display panel to ambient light. This embodiment can integrate the structure of increasing the light extraction efficiency of the light-emitting element 21 and the structure of reducing the reflectivity of the display panel, which can reduce the module thickness of the display panel, therefore being beneficial to improve the overall flexibility of the display panel. In some embodiments, the refractive index of the color filter unit 51 is smaller than the refractive index of the first refractive index unit 31, and the color filter unit 51 is located at the outermost side of the integrated module structure, which can reduce the refractive index difference between the module structure and the layer above it, and thus can reduce the surface reflectivity of the outer surface of the module structure, thereby reducing the reflectivity of the display panel to ambient light and improving the display effect.

As shown in FIG. 5, the black matrix 60 is located on the side of the light-emitting element layer 20 away from the substrate 10, and the first refractive index unit 31 is located in the first opening K1 of the black matrix 60. The second refractive index unit 32, i.e., the color filter unit 51, is at least partially located in the first opening K1. The black matrix 60 can separate adjacent second refractive index units 32 from each other, the black matrix 60 overlaps the pixel definition layer 22, and the black matrix 60 can shield the metal structure under the black matrix 60 from light to prevent the metal structure from reflecting ambient light, so that the reflectivity of the display panel to ambient light can be reduced.

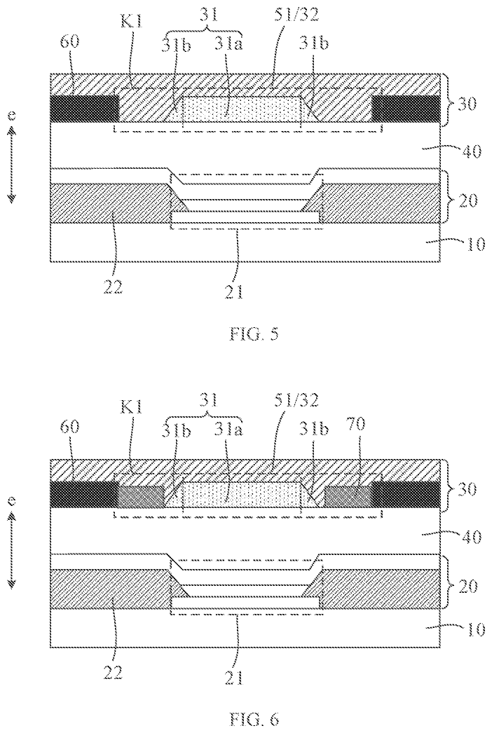

FIG. 6 is a schematic diagram of a display panel according to some embodiments of the present disclosure. In some embodiments, as shown in FIG. 6, the second refractive index unit 32 is reused as a color filter unit 51, and the first refractive index unit 31 is located in the first opening K1. A transparent medium structure 70 is provided between the first refractive index unit 31 and the black matrix 60, and is covered by the second refractive index unit 32. In some embodiments, the transparent medium structure 70 includes optical adhesive. In some embodiments, the cooperation between the second refractive index unit 32 and the first refractive index unit 31 can improve the light extraction efficiency of the light-emitting element 21, and the second refractive index unit 32 also has a filtering function to reduce the reflectivity of the display panel to ambient light. A transparent medium structure 70 is provided between the first refractive index unit 31 and the black matrix 60, which can prevent the local thickness of the second refractive index unit 32 from being too thick to affect the large-angle light extraction of the light-emitting element 21, and thus the large viewing angle color shift can be avoided.

In some embodiments of the present disclosure, the light-emitting elements 21 include a red light-emitting element, a green light-emitting element, and a blue light-emitting element. In some embodiments, at a position overlapping the blue light-emitting element, the transparent medium structure 70 is not filled between the first refractive index unit 31 and the black matrix 60. However, at a position overlapping the green light-emitting element, the transparent medium structure 70 is filled between the first refractive index unit 31 and the black matrix 60. Such an arrangement can balance the differences in the light extracting efficiency and service life of the light-emitting elements of different colors, and improve the service life of the blue light-emitting element by improving the light extraction efficiency of the blue light-emitting element. In addition, among light of three colors (i.e., red, green and blue), human eyes are more sensitive to green light, so that the large viewing angle color shift of the green light-emitting element is avoided, thereby improving the overall display effect of the display panel by avoiding the display color shift.

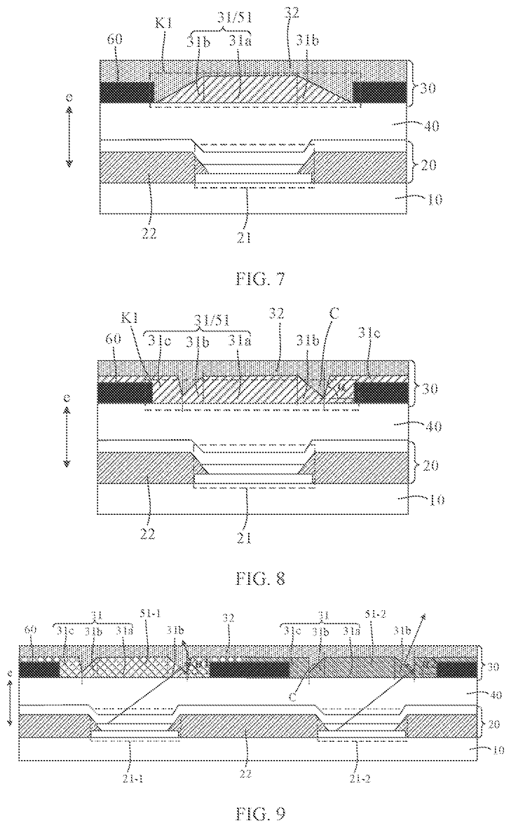

FIG. 7 is a schematic diagram of a display panel according to some embodiments of the present disclosure. In other embodiments, as shown in FIG. 7, the first refractive index unit 31 is reused as a color filter unit 51. The refractive index of the first refractive index unit 31 is greater than the refractive index of the second refractive index unit 32. In other words, the color filter unit 51 is reused as a high refractive index layer in the light extraction layer 30. In some embodiments, the first refractive index unit 31 has a function of increasing the light extraction efficiency of the light-emitting element 21 by cooperating with the second refractive index unit 32, and the first refractive index unit 31 has a characteristic of filtering, which can be used to reduce reflection of the display panel to ambient light. This embodiment can integrate the structure of increasing the light extraction efficiency of the light-emitting element 21 and the structure of reducing the reflectivity of the display panel, which can reduce the module thickness of the display panel, therefore being beneficial to improve the overall flexibility of the display panel. The refractive index of the second refractive index unit 32 is smaller than the refractive index of the first refractive index unit 31, and the second refractive index unit 32 is located at the outermost side of the integrated module structure, which can reduce the refractive index difference between the module structure and the layer above it, and thus reduce the surface reflectivity of the outer surface of the module structure, thereby reducing the reflectivity of the display panel to ambient light and improving the display effect.

As shown in FIG. 7, the display panel further includes a black matrix 60. The black matrix 60 has a first opening K1 in which at least the central portion 31a and the functional portion 31b of the first refractive index unit 31 are located. The first refractive index unit 31 is reused as the color filter unit 51, then the first refractive index unit 31 overlapping the light-emitting element 21 is a patterned structure. The second refractive index unit 32 covers the first refractive index unit 31 and the black matrix 60. The black matrix 60 overlaps the pixel definition layer 22. The black matrix 60 can shield the light emitted by the light-emitting element toward the black matrix 60, so as to reduce the light output to the large-angle direction and improve the large-angle color shift problem. Meanwhile, the black matrix 60 can shield the metal structure under the black matrix 60 from light to prevent the metal structure from reflecting ambient light, so that the reflectivity of the display panel to ambient light can be further reduced.

FIG. 8 is a schematic diagram of a display panel according to some embodiments of the present disclosure. In some embodiments, as shown in FIG. 8, the first refractive index unit 31 is reused as a color filter unit 51. The first refractive index unit 31 further includes an edge portion 31c. The edge portion 31c surrounds the functional portion 31b and is connected to the functional portion 31b. In the direction e perpendicular to the plane of the substrate 10, at least a part of the edge portion 31c overlaps the black matrix 60. FIG. 7 schematically shows that a portion of the edge portion 31c is shown to be located in the first opening K1 of the black matrix 60. In some embodiments, the first refractive index unit 31 forms a three-segment structure (including three segments, i.e., a center portion 31a, a functional portion 31b and an edge portion 31c), that is, the color filter unit 51 forms a three-segment structure. At least a part of the edge portion 31c overlaps the black matrix 60, indicating that the first refractive index unit 31 is located in the first opening K1 of the black matrix 60 and extends outside the first opening K1. The first refractive index unit 31 is reused as a color filter unit 51, so that the color filter unit 51 is deposited at each position in the first opening K1, and the reflected light incident to the first opening K1 in the display panel can pass through the color filter unit 51 to filter, thereby reducing the reflectivity of the display panel to ambient light.

In an embodiment, as shown in FIG. 8, the thickness of the functional portion 31b gradually decreases in the direction from the central portion 31a to the functional portion 31b. The edge portion 31c is connected to the functional portion 31b, and a groove C is formed between the edge portion 31c and the functional portion 31b. The opening of the groove C faces the side facing away from the light-emitting element 21. A first surface (not marked in FIG. 8) at a side of the edge portion 31c close to the functional portion 31b is one groove wall of the groove C. A first angle a pointing to the edge portion 31c and formed between the first surface and a plane parallel to the plane of the substrate satisfies 0°<α≤90°. The first refractive index unit 31 is reused as the color filter unit 51. The color filter unit 51 is usually manufactured by a patterning process. The display panel provided by the present disclosure can be manufactured by using a grayscale lithography technique to obtain a color filter unit 51 with a groove C during a manufacturing process, so as to form the color filter unit 51 with a three-segment structure, that is, to manufacture the first refractive index unit 31 with the three-segment structure. The first refractive index unit 31 has a filtering function, which can reduce the reflectivity of the display panel to ambient light and improve the display effect. Meanwhile, the cooperation of the functional portion 31b in the first refractive index unit 31 with the second refractive index unit 32 can deflect the large-angle light emitted by the light-emitting element 21, so that the light extraction efficiency of the light-emitting element 21 is improved. The embodiments reuse the first refractive index unit 31, which can integrate the structure of increasing the light extraction efficiency of the light-emitting element 21 and the structure of reducing the reflectivity of the display panel, which can reduce the module thickness of the display panel, therefore being beneficial to improve the overall flexibility of the display panel. The second refractive index unit 32 with a smaller refractive index is located at the outmost side of the module structure, the refractive index difference between the module structure and the layer above it can be reduced, thereby reducing the surface reflectivity of the outer surface of the module structure, thereby reducing the reflectivity of the display panel to ambient light, and improving the display effect.

In some embodiments, in the direction e perpendicular to the plane of the substrate 10, a depth of the groove C is not smaller than a half of a thickness of the color filter unit 51.

Such configuration can ensure that the interface in which the functional portion 31b and the second refractive index unit 32 are in contact with each other has a sufficiently large area, so that it can ensure that the functional portion 31b and the second refractive index unit 32 cooperate with each other to deflect more large-angle light, thereby increasing the light extraction efficiency of the light-emitting element 21. The thickness of the color filter unit 51 can be understood as a maximum thickness of the color filter unit in the direction e perpendicular to the plane of the substrate 10.

In the display panel provided by the embodiments of the present disclosure, the light-emitting elements 21 include at least a red light-emitting element, a green light-emitting element, and a blue light-emitting element. Since the surface at a side of the edge portion 31c close to the functional portion 31b can reflect part of the large-angle light emitted by the light-emitting element 21, the viewing angle brightness of the light-emitting element can be affected. In order to reduce the influence of viewing angle brightness on the display effect, another display panel is provided.

FIG. 9 is a schematic diagram of a display panel according to some embodiments of the present disclosure. In some embodiments, as shown in FIG. 9, the light-emitting elements include a first light-emitting element 21-1 and a second light-emitting element 21-2 that emit light of different colors. The first angle of one first refractive index unit 31 overlapping the first light-emitting element 21-1 is α1, and the second angle α2 of another first refractive index unit 31 overlapping the second light-emitting element 21-2 is α2, where α1<α2. In some embodiments, the first refractive index unit 31 is reused as a color filter unit, and then the color of the color filter unit matches the color of the light emitted from the light-emitting element below the color filter unit. The first light-emitting element 21-1 overlaps the first color filter unit 51-1, and the second light-emitting element 21-2 overlaps the second color filter unit 51-2. The first color filter unit 51-1 and the second color filter unit 51-2 have different colors. As illustrated in FIG. 9, the first surface of the edge portion 31c close to the functional portion 31b is in contact with the second refractive index unit 32, and there is a difference in refractive index between the edge portion 31c and the second refractive index unit 32, and the light-emitting element The emitted high-angle light are reflected when they strike the edge portion 31c. Comparing the two optical paths shown in FIG. 9, it is assumed that the first light-emitting element 21-1 and the second light-emitting element 21-2 emit large-angle light, respectively, and the two large-angle light beams travel in the same direction. The light emitted by the first light-emitting element 21-1 is seriously deviated from the original large viewing angle direction after being reflected by the surface of the edge portion 31c in the first color filter unit 51-1. After the light emitted by the first light-emitting element 21-1 is reflected by the surface of the edge portion 31c of the first color filter unit 51-1, it is reflected again inside the groove C and can still be emitted in the direction of a large viewing angle. That is, the larger the first angle, the smaller the influence on the light output at the large viewing angle. It can be seen that setting α1<α2 can make the large-angle light output of the second light-emitting element 21-2 less affected by the edge portion 31c, that is, the large-viewing angle brightness of the second light-emitting element 21-2 can be improved. In some embodiments of the present disclosure, the first angles in the first refractive index units 31 corresponding to different colors of light-emitting elements can be set differently. In some embodiments, the second light-emitting element 21-2 emits green light, and the first light-emitting element 21-1 emits red light or blue light, that is, the second light-emitting element 21-2 is a green light-emitting element, human eyes are more sensitive to green light, so as to ensure the large viewing angle brightness of the green light-emitting element, thereby improving the display effect under the large viewing angle of the display panel.

In some embodiments of the present disclosure, the display panel includes display regions with different light transmittances. Compared with the display region with lower light transmittance, the density of light-emitting elements is higher in the display region with higher light transmittance or the area of the light-emitting element is small, so that the overall brightness of the display region with high light transmittance will be low, and the display split screen phenomenon will occur in the display region. In the related art, the brightness of the light-emitting element in the display region with higher transmittance is increased to balance the display brightness of the two regions, but this may affect the service life of the light-emitting element in the display region with higher transmittance. In order to reduce the difference in display brightness between regions with different light transmittances, another display panel is provided.

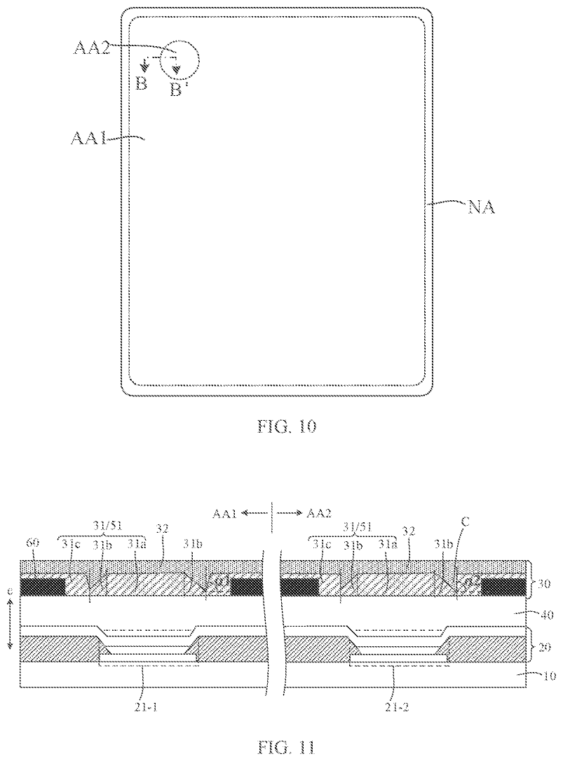

FIG. 10 is a schematic diagram of a display panel according to some embodiments of the present disclosure, and FIG. 11 is a cross-sectional view along line BB′ shown in FIG. 10 according to some embodiments of the present disclosure. In some embodiments, as shown in FIG. 10, the display panel includes a display region AA and a non-display region NA. The display region AA includes a first display region AA1 and a second display region AA2. The light transmittance of the second display region AA2 is greater than the light transmittance of the first display region AA1. The light-emitting elements include a first light-emitting element 21-1 and a second light-emitting element 21-2. The first light-emitting element 21-1 is located in the first display region AA1, and the second light-emitting element 21-2 is located in the second display region AA2. In some embodiments, the density of the second light-emitting elements 21-2 in the second display region AA2 is set to be lower than the density of the first light-emitting elements 21-1 in the first display region AA1, so that the light transmittance of the second display region AA2 is greater than the light transmittance of the first display region AA1. In some embodiments, the area of the second light-emitting element 21-2 in the second display region AA2 is set to be smaller than the area of the first light-emitting element 21-1 in the first display region AA1, so that the light transmittance of the second display region AA2 is greater than the transmittance of the first display region AA1. The second display region AA2 is a reserved region for optical devices, and the optical devices are arranged below the second display region AA2. The ambient light can penetrate the second display region AA2 and then be used by the optical devices to realize optical performances of the optical device. The optical device can be a camera, an infrared sensor, or the like.

As shown in FIG. 11, the first refractive index unit 31 is reused as the color filter unit 51. The first refractive index unit 31 includes a central portion 31a, a functional portion 31b, and an edge portion 31c. A groove C is formed between the edge portion 31c and the functional portion 31b. The first surface at a side of the edge portion 31c close to the functional portion 31b and the plane parallel to the plane of the substrate 10 forms a first angle pointing to the edge portion 31c. The first angle of one first refractive index unit 31 overlapping the first light-emitting element 21-1 is α1, and the first angle a2 of another first refractive index unit 31 overlapping the second light-emitting element 21-2 is a2, where α1<α2. It can be learned from the description in the above embodiments of FIG. 8 that the larger the first angle is, the smaller the influence on the light output of the large viewing angle light. That is, the larger the first angle is, the more light is emitted with a large viewing angle, which can increase the total light output amount of the light-emitting elements and improve the light extraction efficiency of the light-emitting elements. When α1<α2, the large-angle light output of the second light-emitting element 21-2 is less affected by the edge portion 31c, and the light output of the second light-emitting element 21-2 is increased, so that the light extraction efficiency of the second light-emitting element 21-2 is greater than the light extraction efficiency of the first light-emitting element 21-1. The brightness of the second light-emitting element 21-2 can be increased by improving the light extraction efficiency of the second light-emitting element 21-2, thereby balancing the brightness difference between the second display region AA2 and the first display region AA1, reducing the phenomenon of display split screen, and improving the display effect.

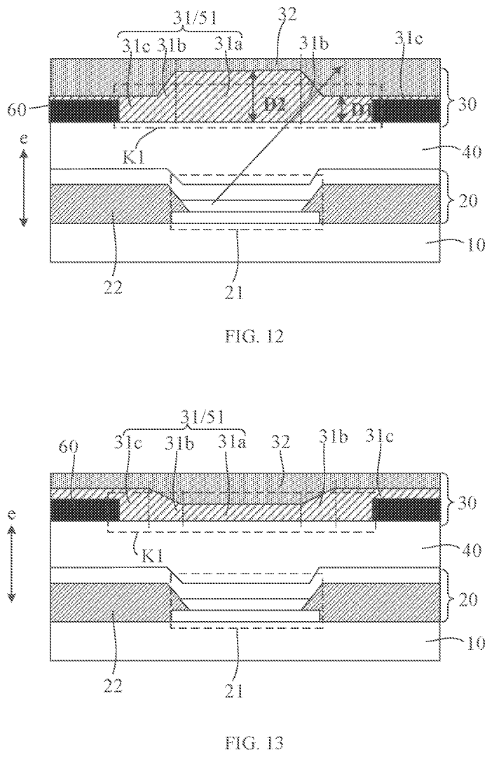

FIG. 12 is a schematic diagram of a display panel according to some embodiments of the present disclosure. In some embodiments, as shown in FIG. 12, a vertical distance D1 from the surface of the edge portion 31c away from the substrate 10 to the substrate 10, and a vertical distance D2 from the surface of the center portion 31a away from the substrate 10 to the substrate 10 satisfy: D1<D2. The edge portion 31c is connected to the functional portion 31b, and at least a part of the edge portion 31c overlaps the black matrix 60 in the direction e perpendicular to the plane of the substrate 10. In some embodiments, the first refractive index unit 31 forms a three-segment structure, that is, the color filter unit 51 forms the three-segment structure. At least a part of the edge portion 31c overlaps the black matrix 60, indicating that the first refractive index unit 31 is located in the first opening K1 of the black matrix 60 and extends outside the first opening K1. The first refractive index unit 31 is reused as the color filter unit 51, so that the color filter unit 51 is deposited at each position in the first opening K1, and the reflected light incident to the first opening K1 in the display panel can pass through the color filter unit 51 to filter, thereby reducing the reflectivity of the display panel to ambient light. By setting D1<D2, the large-angle refracted light passing through the interface where the functional portion 31b is in contact with the second refractive index unit 32 can directly penetrate the second refractive index unit 32, so that the light output of a large viewing angle light can be ensured, thereby ensuring the display brightness under a large viewing angle.

The above embodiments exemplify the case where the refractive index of the first refractive index unit 31 is greater than the refractive index of the second refractive index unit 32, and the thickness of the functional portion 31b gradually decreases in the direction from the central portion 31a to the functional portion 31b. The following will exemplify some embodiments in which the refractive index of the first refractive index unit 31 is smaller than the refractive index of the second refractive index unit 32, and the thickness of the functional portion 31b gradually increases in the direction from the central portion 31a to the functional portion 31b.

FIG. 13 is a schematic diagram of a display panel according to some embodiments of the present disclosure. In some embodiments, as shown in FIG. 13, the refractive index of the first refractive index unit 31 is smaller than the refractive index of the second refractive index unit 32, the display panel includes a color filter unit 51, and the first refractive index unit 31 is reused as the color filter unit 51. In other words, the color filter unit 51 is reused as the first refractive index unit 31, that is, the color filter unit 51 is reused as the low refractive index layer in the light extraction layer 30. In some embodiments, the first refractive index unit 31 can increase the light extraction efficiency of the light-emitting element 21 by cooperating with the second refractive index unit 32, and the first refractive index unit 31 has a characteristic of filtering, which can be used to reduce reflection of the display panel to ambient light. The embodiments can integrate the structure of increasing the light extraction efficiency of the light-emitting element 21 and the structure of reducing the reflectivity of the display panel, which can reduce the module thickness of the display panel, therefore being beneficial to improve the overall flexibility of the display panel.

As shown in FIG. 13, the first refractive index unit 31 can include an edge portion 31c. The edge portion 31c surrounds the functional portion 31b and is connected to the functional portion 31b. The functional portion 31b and the central portion 31a are located in the first opening K1 of the black matrix 60. In the direction e perpendicular to the plane of the substrate 10, at least a part of the edge portion 31c overlaps the black matrix 60. That is, the black matrix 60 is located on the side of the color filter unit 51 close to the substrate 10. During a manufacturing process, and the black matrix 60 is first manufactured, and then the color filter unit 51 is manufactured. In some embodiments, the first refractive index unit 31 forms a three-segment structure, and is reused as the color filter unit 51, so that the color filter unit 51 is deposited in the whole first opening Kl, and the reflected light incident to the first opening K1 in the display panel can pass through the color filter unit 51 to filter, thereby reducing the reflectivity of the display panel to ambient light.

In some embodiments, as shown in FIG. 5 or FIG. 13, the central portion 31a and the functional portion 31b of the first refractive index unit 31 are located in the first opening K1 of the black matrix 60. In some embodiments of the present disclosure, the color filter unit 51 is reused as the first refractive index unit 31 in the light extraction layer 30, or the color filter unit 51 is reused as the second refractive index unit 32, the structure of increasing the light extraction efficiency of the light-emitting element 21 and the structure of reducing the reflectivity of the display panel can be integrated, which can reduce the module thickness of the display panel, and is beneficial to improve the overall flexibility of the display panel. The central portion 31a and the functional portion 31b of the first refractive index unit 31 are arranged in the first opening K1 of the black matrix 60. The black matrix 60 can not only separate the adjacent color filter unit 51 from each other, but also can shield light for the metal structure located under black matrix 60, thereby reducing the reflection of ambient light by the metal structure. In the embodiments of the present disclosure realizes that the surfaces at a side of the center portion 31a and the functional portion 31b close to the substrate 10, and the surface at a side of the black matrix 60 close to the substrate 10 can be in contact with the same base layer, so that the black matrix 60 can be integrated in the structure of increasing the light extraction efficiency of the light-emitting element 21 and the structure of reducing the reflectivity of the display panel, and the thickness of the module of the display panel can be reduced, thereby improving the overall flexibility of the display panel.

In some embodiments of the present disclosure, the functional portion 31b has a tangent angle θ, where 40°≤θ≤80°, and the thickness of the functional portion 31b gradually changes in the direction from the center portion 31a to the functional portion 31b. The shape of the functional portion 31b can be as shown in FIG. 2 or FIG. 3, and the second surface M2 at a side of the functional portion 31b away from the substrate 10 is a flat plane. In some embodiments of FIG. 2 or FIG. 3, an angle pointing to the functional portion 31b and formed between the second surface M2 (a flat plane) and a plane parallel to the plane of the substrate 10 is the tangent angle θ. In other embodiments, the second surface M2 on the side of the functional portion 31b away from the substrate 10 is a curved surface. FIG. 14 is a partial schematic diagram of a display panel according to some embodiments of the present disclosure. FIG. 14 schematically shows that the thickness of the functional portion 31b gradually decreases in the direction from the central portion 31a to the functional portion 31b. As shown in FIG. 4, when the second surface M2 on the side of the functional portion 31b away from the substrate 10 is a curved surface, an angle pointing to the functional portion 31b and formed between the tangent plane of the second surface M2 and the plane parallel to the substrate 10 is the tangent angle θ. The tangent angle θ is not shown in FIG. 14, and the tangent plane can be understood with reference to the concept of tangent plane in mathematical sciences, which will not be repeated herein.

In other embodiments, in the direction from the central portion 31a to the functional portion 31b, the thickness of the functional portion 31b gradually increases, and the second surface M2 on the side of the functional portion 31b away from the substrate 10 is a curved surface, which is not shown in the drawings.

In some embodiments of the present disclosure, the interface in which the second surface M2 and the second refractive index unit 32 are in contact with each other is used to deflect the large-angle light entering the second refractive index unit 32 from the functional portion 31b, and the value of the tangent angle θ of the functional portion 31b are defined. It can be understood that there is a large acute angle formed between the large-angle light and the front viewing direction, and the interface in which the functional portion 31b and the second refractive index unit 32 are in contact with each other can deflect the propagation direction of the large-angle light. Part of the large-angle light under the action of the interface in which the functional portion 31b and the second refractive index unit 32 are in contact with each other is deflected toward a direction away from the front viewing direction. That is to say, when the value of the tangent angle θ is fixed, the large-angle light that can serve to improve the light extraction efficiency of the light-emitting element 21 occupy a certain proportion of all the large-angle light emitted by the light-emitting element 21. As the value of the tangent angle θ increases from small to large, the proportion of large-angle light that can serve to improve the light extraction efficiency of the light-emitting element 21 first increases and then decreases. In some embodiments of the present disclosure, 40°≤θ≤80°, so that the large-angle light that can improve the light extraction efficiency of the light-emitting element 21 occupies a large proportion of all the large-angle light emitted by the light-emitting element 21, that is, most of the large-angle light deflects in a direction close to the front viewing direction after being refracted by the interface in which the second surface M2 and the second refractive index unit 32 are in contact with each other, which contributes to increasing the light extraction efficiency of the light-emitting element 21.

In some embodiments, 45°≤θ≤65°.

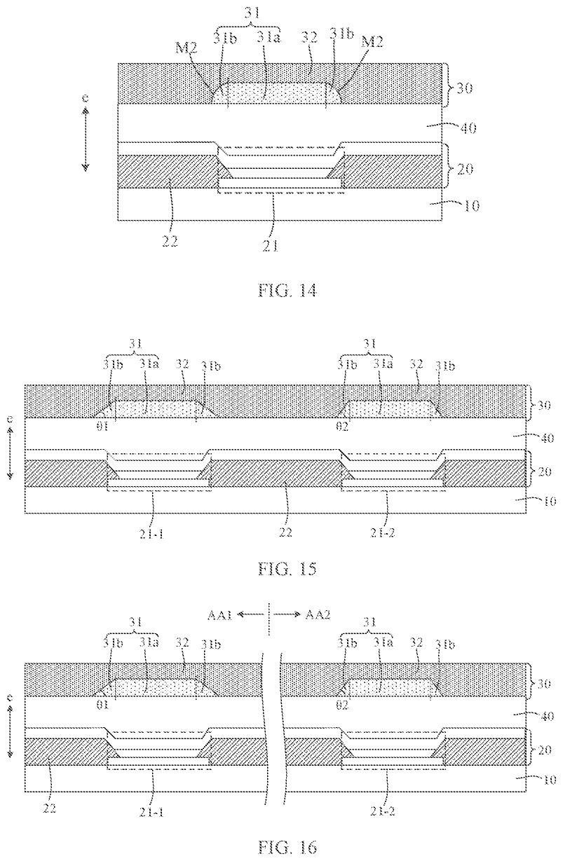

In the display panel provided by the embodiments of the present disclosure, the light-emitting elements 21 include at least a red light-emitting element, a green light-emitting element, and a blue light-emitting element, however, the service lives of the light-emitting elements emitting light of different colors are different from each other. The tangent angles 0 in the first refractive index units 31 corresponding to the light-emitting elements 21 emitting light of different colors have different values, so as to compensate for the difference in service life between the light-emitting elements 21 emitting light of different colors. FIG. 15 is another partial schematic diagram of a display panel according to some embodiments of the present disclosure. In some embodiments, as shown in FIG. 15, the light-emitting elements include a first light-emitting element 21-1 and a second light-emitting element 21-2 that emit light of different colors. The tangent angle of one first refractive index unit 31 overlapping the first light-emitting element 21-1 is θ1, and the tangent angle of another first refractive index unit 31 overlapping the second light-emitting element 21-2 is θ2, where θ1<θ2. When the value of the tangent angle satisfies a certain range, the larger the tangent angle is, more large-angle light can be deflected by the contact interface between the functional portion 31b and the second refractive index unit 32. If θ1<θ2, the increase of the light extraction efficiency of the second light-emitting element 21-2 is greater than the light extraction efficiency of the first light-emitting element 21-1, that is, the light extraction efficiency of the second light-emitting element 21-2 can be improved more, so that the service lives of the second light-emitting elements 21-2 can be improved.

In some embodiments, the second light-emitting element 21-2 emits blue light, and the first light-emitting element 21-1 emits red light or green light.

In the embodiments of FIG. 15, the thickness of the functional portion 31b gradually decreases in the direction from the center portion 31a to the functional portion 31b. In other embodiments, the thickness of the functional portion 31b gradually increases in the direction from the central portion 31a to the functional portion 31b. The values of the tangent angles θ of the first refractive index units 31 overlapping the light-emitting elements emit light of different colors in the display panel are designed to be different from each other, which are not shown in the drawing.

In other embodiments, the present disclosure makes the values of the tangent angles θ of the first refractive index units 31 in regions with different light transmittances to be different from each other. FIG. 16 is a cross-sectional view along line BB′ shown in FIG. 10 according to some embodiments of the present disclosure. As shown in FIG. 16, the first light-emitting element 21-1 is located in the first display region AA1, and the second light-emitting element 21-2 is located in the second display region AA2. The tangent angle of one first refractive index unit overlapping the first light-emitting element 21-1 is θ1, and the tangent angle of another first refractive index unit 31 overlapping the second light-emitting element 21-2 is θ2, where θ1<θ2. In this way, the light extraction efficiency of the second light-emitting element 21-2 can be higher than the light extraction efficiency of the first light-emitting element 21-1, so that the brightness of the second light-emitting element 21-2 can be improved by improving the light extraction efficiency of the second light-emitting element 21-2, thereby balancing the difference between the brightness in the second display region AA2 and the brightness in the first display region AA1, reducing the display split screen phenomenon, and improving the display effect.

In the embodiments of FIG. 16, for example, the thickness of the functional portion 31b gradually decreases in the direction from the center portion 31a to the functional portion 31b. In other embodiments, the thickness of the functional portion 31b gradually increases in the direction from the central portion 31a to the functional portion 31b. The values of the tangent angles 0 in the first refractive index units 31 overlapping the regions with different light transmittances in the display panel are designed differently, which are not shown in the drawing.

In some embodiments, the functional portions 31b of the first refractive index units 31 overlapping different light-emitting elements 21 have different maximum thicknesses, so as to adjust the light extraction efficiency of the light-emitting element 21 by adjusting the thicknesses of the functional portions 31b.

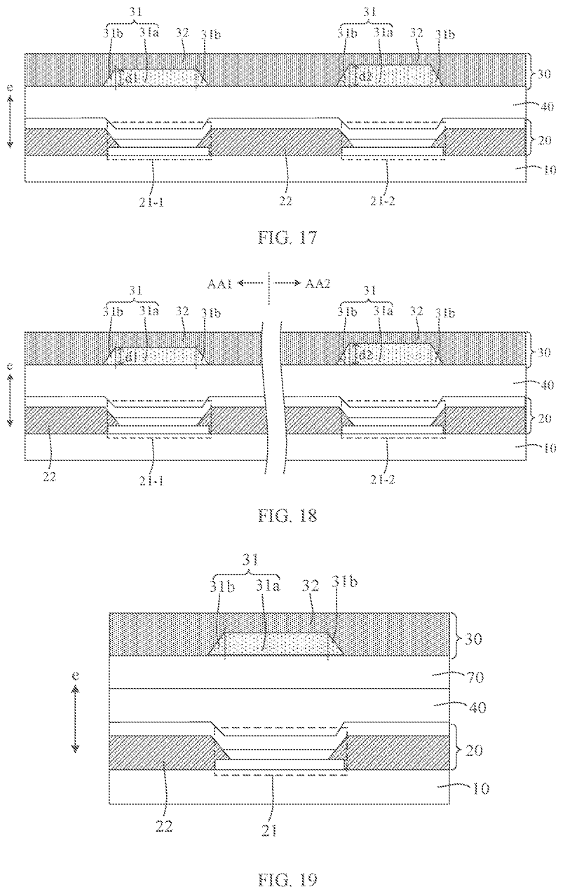

In some embodiments, the functional portions 31b of the first refractive index units 31 corresponding to the light-emitting elements 21 emitting light of different colors have different maximum thicknesses to compensate for the difference in service life between the light-emitting elements 21 emitting light of different colors. FIG. 17 is another partial schematic diagram of a display panel according to some embodiments of the present disclosure. As shown in FIG. 17, the first light-emitting element 21-1 and the second light-emitting element 21-2 emit light of different colors. A maximum thickness d1 of the functional portion 31b in one first refractive index unit overlapping the first light-emitting element 21-1, and a maximum thickness d2 of the functional portion 31b in another first refractive index unit 31 overlapping the second light-emitting element 21-2 satisfy d1<d2. FIG. 17 schematically shows that the thickness of the functional portion 31b gradually decreases in the direction from the central portion 31a to the functional portion 31b, and then the maximum thickness of the functional portion 31b is located at the contact position between the functional portion 31b and the central portion 31a. Increasing the maximum thickness of the functional portion 31b can increase the area of a side surface of the functional portion 31b away from the substrate 10, i.e., the contact area between the functional portion 31b and the second refractive index unit 32 can be increased, so that more large-angle light emitted by the light-emitting element 21 can be deflected to improve the light extraction efficiency of the light-emitting element 21. If d1<d2, the increase of the light extraction efficiency of the second light-emitting element 21-2 is greater than the light extraction efficiency of the first light-emitting element 21-1, that is, the light extraction efficiency of the second light-emitting element 21-2 can be improved, so that the service life of the second light-emitting element 21-2 can be improved.

In the embodiments of FIG. 17, the thickness of the functional portion 31b gradually decreases in the direction from the center portion 31a to the functional portion 31b. In other embodiments, the thickness of the functional portion 31b gradually increases in the direction from the central portion 31a to the functional portion 31b. The functional portions 31b of the first refractive index units 31 overlapping the light-emitting elements emitting light of different colors have different maximum thicknesses.

In some embodiments, the first refractive index units 31 are reused as color filter units, and color filter units of different colors have different light transmittances. The light transmittance of the color filter unit can be designed to cooperate with the maximum thickness of the functional portion 31b. The higher the light transmittance of the color filter unit, the greater the maximum thickness of the functional portion 31b, which can increase the light extraction efficiency of the light-emitting element 21.

In other embodiments, the present disclosure provides different maximum thicknesses of the functional portions 31b in the first refractive index units 31 in the regions with different light transmittances. FIG. 18 is another cross-sectional view along line BB′ shown in FIG. 10 according to some embodiments of the present disclosure. As shown in FIG. 18, the first light-emitting element 21-1 is located in the first display region AA1, and the second light-emitting element 21-2 is located in the second display region AA2. A maximum thickness d1 of the functional portion 31b in one first refractive index unit overlapping the first light-emitting element 21-1, and a maximum thickness d2 of the functional portion 31b in another first refractive index unit 31 overlapping the second light-emitting element 21-2 satisfy d1<d2. In this way, the light extraction efficiency of the second light-emitting element 21-2 can be higher than the light extraction efficiency of the first light-emitting element 21-1, so that the brightness of the second light-emitting element 21-2 can be increased by increasing the light extraction efficiency of the second light-emitting element 21-2, thereby balancing the brightness difference between the second display region AA2 and the first display region AA1, reducing the display split screen phenomenon, and improving the display effect.

In the embodiments of FIG. 18, for example, the thickness of the functional portion 31b gradually decreases in the direction from the center portion 31a to the functional portion 31b. In other embodiments, the thickness of the functional portion 31b gradually increases in the direction from the central portion 31a to the functional portion 31b. The functional portions 31b in the first refractive index units 31 overlapping the regions with different light transmittances in the display panel have different maximum thicknesses, which are not shown in the drawing.

In some embodiments, the display panel further includes a touch layer. FIG. 19 is a schematic diagram of a display panel according to some embodiments of the present disclosure. As shown in FIG. 19, the display panel further includes a touch layer 70 located between an encapsulation layer 40 and a light extraction layer 30. The touch layer 70 includes a touch electrode. The touch layer 70 can realize the touch function of the display panel. FIG. 19 illustrates the layer position of the touch layer in the display panel, in which only one specific structure of the light extraction layer 30 is illustrated.

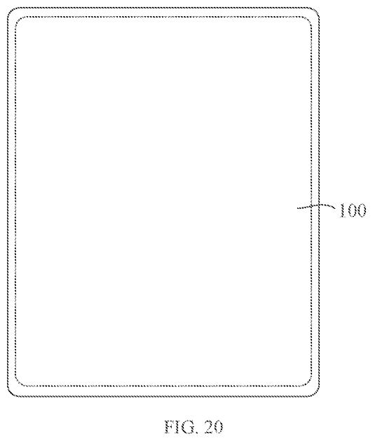

The present disclosure further provides a display apparatus. FIG. 20 is a schematic diagram of a display apparatus according to some embodiments of the present disclosure. As shown in FIG. 20, the display apparatus includes the display panel 100 provided by any embodiment of the present disclosure. The structure of the display panel has been described in the above embodiments of the display panel, which will not be repeated herein. The display apparatuses provided by the embodiments of the present disclosure include any electronic device with a display function, such as a mobile phone, a computer, a tablet computer, a TV, a vehicle-mounted display, a smart wearable device or the like.

The above embodiments are merely some exemplary embodiments of the present disclosure, which, as mentioned above, are not used to limit the present disclosure. Any modification, equivalent substitution, improvement, etc., made within the principle of the present disclosure shall fall into the protection scope of the present disclosure.

Finally, it should be noted that the technical solutions of the present disclosure are illustrated by the above embodiments, but not intended to limit thereto. Although the present disclosure has been described in detail with reference to the foregoing embodiments, those skilled in the art can understand that the present disclosure is not limited to the above embodiments described herein, and those skilled in the art can make various obvious modifications, readjustments, and substitutions without departing from the scope of the present disclosure.

What is claimed is:

1. A display panel, comprising:
a substrate;
a light-emitting element layer located on a side of the substrate, wherein the light-emitting element layer comprises light-emitting elements; and
a light extraction layer located on a side of the light-emitting element layer away from the substrate,
wherein the light extraction layer comprises at least one first refractive index unit and a second refractive index unit, wherein a refractive index of each of the at least one first refractive index unit is different from a refractive index of the second refractive index unit;
wherein, in a direction perpendicular to a plane of the substrate, one of the at least one first refractive index unit overlaps one of the light-emitting elements; and each of the at least one first refractive index unit comprises a central portion and a functional portion surrounding the central portion, wherein the functional portion has a thickness changing gradually in a direction from the central portion to the functional portion; and
wherein the second refractive index unit is located on a side of the at least one first refractive index unit away from the substrate and covers at least the functional portion.

2. The display panel according to claim 1, wherein
the refractive index of each of the at least one first refractive index unit is greater than the refractive index of the second refractive index unit; and
the thickness of the functional portion gradually decreases in the direction from the central portion to the functional portion.

3. The display panel according to claim 2, comprising:
a color filter layer comprising a color filter unit and located on a side of the light extraction layer away from the light-emitting element layer.

4. The display panel according to claim 3, wherein
a refractive index of the color filter unit is smaller than the refractive index of each of the at least one first refractive index unit.

5. The display panel according to claim 2, further comprising:
a color filter layer comprising a color filter unit, wherein the second refractive index unit is reused as the color filter unit; and
a black matrix located on the side of the light-emitting element layer away from the substrate, wherein the black matrix has at least one first opening, wherein one of the at least one first refractive index unit is located within one of the at least one first opening, and a transparent medium structure is arranged between the one of the at least one first refractive index unit and the one of the at least one black matrix.

6. The display panel according to claim 2, comprising:
a color filter layer comprising at least one color filter unit, wherein the at least one first refractive index unit is reused as the at least one color filter unit.

7. The display panel according to claim 6, further comprising:
a black matrix located on the side of the light-emitting element layer away from the substrate, wherein the black matrix has at least one first opening, wherein the center portion and the functional portion of one of the at least one first refractive index unit are located within one of the at least one first opening.

8. The display panel according to claim 7, wherein
each of the at least one first refractive index unit further comprises an edge portion surrounding the functional portion and connected to the functional portion; and
in the direction perpendicular to the plane of the substrate, at least a part of the edge portion overlaps the black matrix.

9. The display panel according to claim 8, wherein
a groove is formed between the edge portion and the functional portion, and a first surface of the edge portion close to the functional portion is a groove wall of the groove; and
a first angle a pointing to the edge portion and formed between the first surface and a plane parallel to the plane of the substrate satisfies 0°<α≤90°.

10. The display panel according to claim 9, wherein
the light-emitting elements comprise a first light-emitting element and a second light-emitting element; and
the at least one first refractive index unit comprises at least two first refractive index units, the first angle of one of the at least two first refractive index units that overlaps the first light-emitting element is α1, and the first angle of another one of the at least two first refractive index units that overlaps the second light-emitting element is α2, where α1<α2.

11. The display panel according to claim 8, wherein
a vertical distance from a surface of the edge portion away from the substrate to the substrate is a first distance, and a vertical distance from a surface of the central portion away from the substrate to the substrate is a second distance, wherein the first distance is smaller than the second distance.

12. The display panel according to claim 1, wherein
the refractive index of each of the at least one first refractive index unit is smaller than the refractive index of the second refractive index unit; and
the thickness of the functional portion gradually increases in the direction from the central portion to the functional portion.

13. The display panel according to claim 12, further comprising:
a color filter layer comprising at least one color filter unit, wherein the at least one first refractive index unit is reused as the at least one color filter unit; and
a black matrix located on the side of the light-emitting element layer away from the substrate and having at least one first opening,
wherein each of the at least one first refractive index unit further comprises an edge portion surrounding the functional portion and connected to the functional portion; and
wherein, in the direction perpendicular to the plane of the substrate, at least a part of the edge portion overlaps the black matrix.

14. The display panel according to claim 1, further comprising:
a black matrix located on the side of the light-emitting element layer away from the substrate, wherein the black matrix has at least one first opening, wherein the central portion and the functional portion of one of the at least one first refractive index unit are located within one of the at least one first opening.

15. The display panel according to claim 1, wherein
the functional portion has a tangent angle θ, where 40°≤θ≤80°; and
when a second surface of the functional portion away from the substrate is a flat plane, an angle pointing to the functional portion and formed between the second surface and a plane parallel to the substrate is the tangent angle θ; or when the second surface of the functional portion away from the substrate is a curved plane, an angle pointing to the functional portion and formed between a tangent plane of the second surface and the plane parallel to the substrate is the tangent angle θ.

16. The display panel according to claim 15, wherein
the light-emitting elements comprise a first light-emitting element and a second light-emitting element; and
the at least one first refractive index unit comprises at least two first refractive index units, the tangent angle of one of the at least two first refractive index units that overlaps the first light-emitting element is θ1, and the tangent angle of another one of the at least two first refractive index units that overlaps the second light-emitting element is θ2, where θ1<θ2.

17. The display panel according to claim 1, wherein
the light-emitting elements comprise a first light-emitting element and a second light-emitting element; and
the at least one first refractive index unit comprises at least two first refractive index units, a maximum thickness d1 of the functional portion of one of the at least two first refractive index units that overlaps the first light-emitting element and a maximum thickness d2 of the functional portion of another one of the at least two first refractive index units that overlaps the second light-emitting element satisfy d1<d2.

18. The display panel according to claim 11, wherein
the first light-emitting element and the second light-emitting element are configured to emit light of different colors.

19. The display panel according to claim 11, wherein
the display panel has a display region comprising a first display region and a second display region, wherein light transmittance of the second display region is greater than light transmittance of the first display region; and
the first light-emitting element is located in the first display region, and the second light-emitting element is located in the second display region.

20. A display apparatus, comprising a display panel,
wherein the display panel comprises:
a substrate;
a light-emitting element layer located on a side of the substrate, wherein the light-emitting element layer comprises light-emitting elements; and
a light extraction layer located on a side of the light-emitting element layer away from the substrate,
wherein the light extraction layer comprises at least one first refractive index unit and a second refractive index unit, wherein a refractive index of each of the at least one first refractive index unit is different from a refractive index of the second refractive index unit;
wherein, in a direction perpendicular to a plane of the substrate, one of the at least one first refractive index unit overlaps one of the light-emitting elements; and each of the at least one first refractive index unit comprises a central portion and a functional portion surrounding the central portion, wherein the functional portion has a thickness changing gradually in a direction from the central portion to the functional portion; and
wherein the second refractive index unit is located on a side of the at least one first refractive index unit away from the substrate and covers at least the functional portion.
